(19) United States
(12) Patent Application Publication
(10) Pub. No.: US 2011/0157856 A1
(43) Pub. Date: Jun. 30, 2011

(54) ELECTRONIC DEVICE PROVIDED WITH SUBSTRATES

(75) Inventor: Naoyuki KIKUCHI, Tokyo-to (JP)

(73) Assignee: J&K CAR ELECTRONICS CORPORATION, Tokyo (JP)

(21) Appl. No.: 12/974,340

(22) Filed: Dec. 21, 2010

(30) Foreign Application Priority Data
Dec. 25, 2009 (JP) P2009-294685

(51) Int. Cl. H05K 7/14

(52) U.S. Cl. 361/796

(57) ABSTRACT

An electronic device includes a main substrate, a top board, a daughter substrate and a storage case. The main substrate is provided with an electronic part. The top board is arranged above the main substrate. The daughter substrate is electronically connected to the main substrate. The storage case accommodates the daughter substrate and is mounted to the top board at an inner surface side of the top board.

### BACKGROUND OF THE INVENTION

1. Field of the Invention

The present invention relates to an electronic device provided with substrates in which a mounting configuration of the substrates is improved.

2. Description of the Related Art

In a conventional electronic device such as in-vehicle electronic device, there are many cases where a daughter substrate smaller than a main substrate is additionally connected to the main substrate for carrying out a main control of members to which various electronic parts are mounted. In general, the daughter substrate is arranged in parallel with the main substrate via a spacer and electronically connected to the main substrate via a connector or a cable. In a case where a high frequency part is mounted to a substrate, a shield case is mounted so as to surround the high frequency part (for example, Japanese Patent Application Laid-Open Nos. 2009-272556, 2007-329735, 2009-247007 and 2009-212121).

For example, in a case where daughter substrates with high frequency parts are mounted to a main substrate, an electronic device which includes the main substrate and the daughter substrates therein has a mounting configuration shown in FIG. 1. Namely, the daughter substrates 102 are arranged on the main substrate 101, electronically connected to the main substrate 101, and covered with a shield case 103.

However, in the case where the electronic device has the above-described mounting configuration, it is necessary to provide mounting spaces where the daughter substrates 102 are arranged on the main substrate 101, which reduces spaces where electronic parts are arranged on the main substrate 101. In addition, in the case where the daughter substrates 102 are covered with the shield case 103, this further reduces spaces where electronic parts are arranged on the main substrate 101. Thus, the conventional mounting configuration of daughter substrate reduces a degree of freedom of a pattern design in the main substrate, which burdens a designer with the pattern design.

### SUMMARY OF THE INVENTION

The present invention has an object to provide an electronic device in which a daughter substrate can be mounted in a housing without reducing a degree of freedom of a pattern design in the main substrate.

In order to achieve the above-described object, the present invention provides an electronic device comprising: a main substrate provided with an electronic part; a top board arranged above the main substrate; a daughter substrate electronically connected to the main substrate; and a storage case accommodating the daughter substrate and mounted to the top board at an inner surface side of the top board.

In a preferred embodiment of the present invention, the top board is a part of a housing cover covering the main substrate.

In a preferred embodiment of the present invention, the storage case is formed in a shape of a concave portion to have an open portion on an upper surface thereof and mounted to the top board such that the open portion is opposed to the top board.

In a preferred embodiment of the present invention, the storage case and the top board are made from conductive material and the inside of the concave portion is electromagnetically-shield.

According to the present inventions, since the daughter substrate is not mounted on the main substrate directly, this mounting configuration increases a degree of freedom of a pattern design in the main substrate.

### BRIEF DESCRIPTION OF THE DRAWINGS

FIG. 1 is an explanatory diagram that explains a conventional mounting configuration in which daughter substrates and a shield case are mounted to a main substrate.

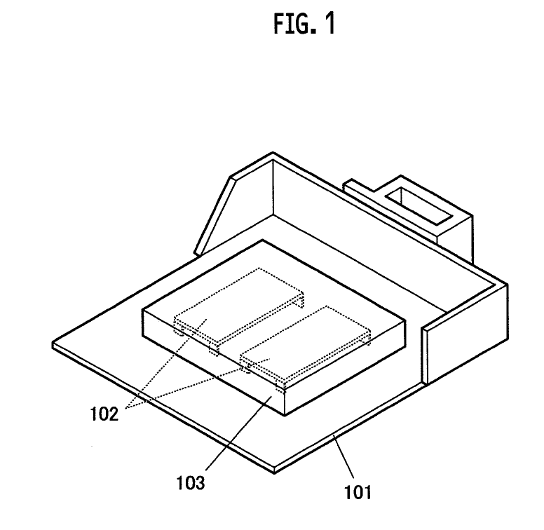

FIG. 2 is a front diagram that illustrates a mounting configuration of substrates in an in-vehicle electronic device according to an exemplary embodiment of the present invention.

FIG. 3 is an exploded perspective diagram that illustrates the mounting configuration of the substrates according to the exemplary embodiment of the present invention.

FIG. 4 is a perspective diagram that illustrates a storage embodiment of daughter substrates according to the exemplary embodiment of the present invention.

FIG. 5 is a plane diagram that illustrates the storage embodiment of the daughter substrates according to the exemplary embodiment of the present invention.

### DESCRIPTION OF THE EMBODIMENTS

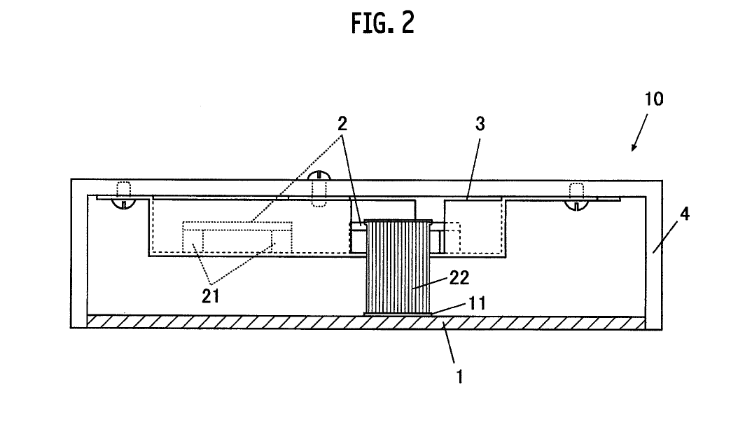

An exemplary embodiment of the present invention will be described below, with reference to FIGS. 2 to 5. The present embodiment cites a case where daughter substrates are mounted to a main substrate in an in-vehicle electronic device of 1 DIN type.

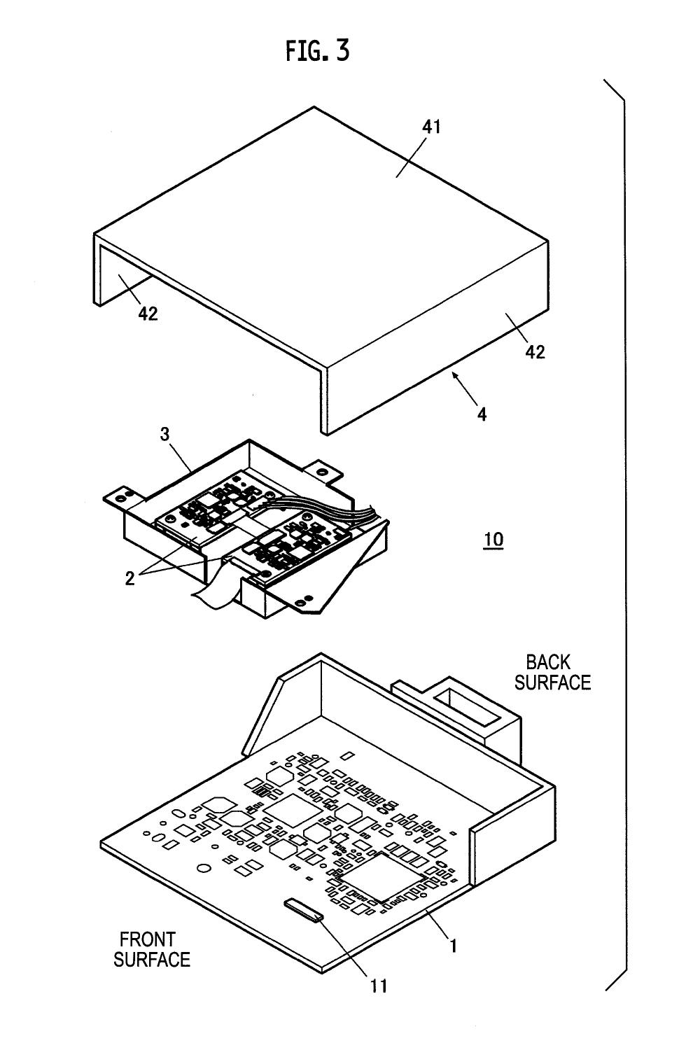

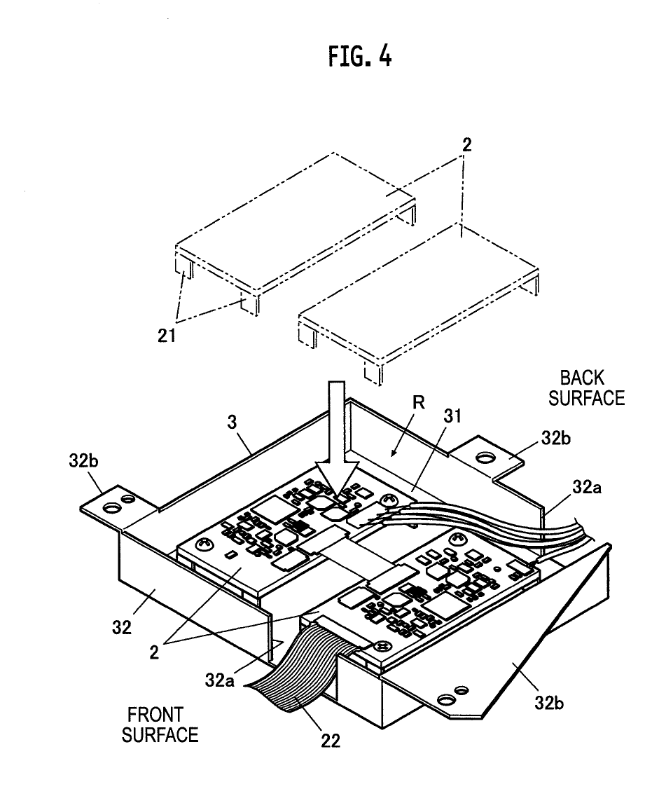

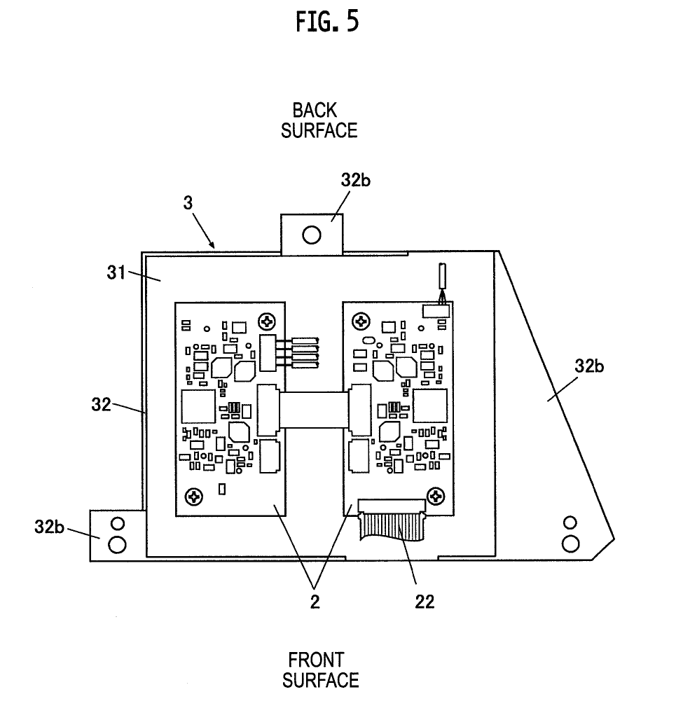

FIG. 2 is a front diagram that illustrates a mounting configuration of substrates in an in-vehicle electronic device. FIG. 3 is an exploded perspective diagram that illustrates the mounting configuration of the substrates. FIG. 4 is a perspective diagram that illustrates a storage embodiment of daughter substrates. FIG. 5 is a plane diagram that illustrates the storage embodiment of the daughter substrates.

As shown in FIGS. 2 to 5, an in-vehicle electronic device 10 includes a main substrate 1, daughter substrates 2, a storage case 3 and a housing cover 4.

The main substrate 1 is a circuit substrate with various electronic parts (not shown) and carries out a main control of the in-vehicle electronic device 10. Each daughter substrate 2 is a small circuit substrate (for example, high-frequency circuit such as tuner circuit) for adding specific function to the main substrate 1. Each daughter substrate 2 has spacers 21 on the bottom surface thereof and is mounted on a bottom wall 31 of the storage case 3 via the spacers 21. A card line 22 has one end connected to one daughter substrate 2 and the other end connected to a connector 11 of the main substrate 1.

It is noted that if the storage case 3 can accommodate the daughter substrates 2, the size and shape of each daughter substrate 2 and the number of daughter substrates 2 are not subject to specific limitations. Also, it is noted that the daughter substrates 2 may be directly screwed and fixed to the storage case 3 without mounting the spacers 21 to each daughter substrate 2.

As shown in FIGS. 3 and 4, the storage case 3 is made from a sheet metal member and molded into a shape of a concave portion by sheet-metal processing to have an open portion on the upper surface thereof. The daughter substrates 2 are received in a concave portion R formed by the bottom wall 31 and a surrounding wall 32 of the storage case 3. Cutting portions 32a are formed on a front surface and a back surface of the surrounding wall 32, and used to introduce cables and the card line 22 connected to the daughter substrates 2 to the outside of the storage case 3. Mounting portions 32b with screw holes are formed on upper lines of a left side surface, a right side surface and the back surface of the surrounding wall 32, and used to screw the storage case 3 to the housing cover 4.

The housing cover 4 is made from a sheet metal member and molded into a substantially U-letter shape viewed from side by sheet-metal processing to have open portions on a front surface and a back surface thereof. The housing cover 4 is fixed to the main substrate 1 using proper engagement means (not shown) under a state where inner surfaces of lower portions of left and right side walls 42 abut on left and right side surfaces of the main substrate 1.

In the present embodiment, the daughter substrates 2 are mounted on the bottom wall 31 of the storage case 3, and then the storage case 3 on which the daughter substrates 2 are mounted is suspended from the upper surface 41 of the housing cover 4 at an inner surface side of the housing cover 4. By the storage case 3 and the housing cover 4 made from metal material, the inside of the concave portion R of the storage case 3 is electromagnetically-shield (so-called “electromagnetic shield”). This prevents noise due to electromagnetic wave from occurring in the daughter substrates 2.

Then, the housing cover 4 from which the storage case 3 is suspended is mounted to the main substrate 1, which mounts the daughter substrates 2 and the storage case 3 to the main substrate 1. Under this configuration, one daughter substrate 2 is electronically connected to the main substrate 1 via the card line 22.

It is noted that a front surface panel including a display and an operation key is mounted to a front surface side of the main substrate 1.

Thus, in the mounting configuration of the substrates according to the present embodiment, a top board (the upper surface 41 of the housing cover 4) is arranged above the main substrate 1 and the storage case 3 to which the daughter substrates 2 are mounted is suspended from the top board.

This mounting configuration makes use of space between the main substrate 1 and the upper surface 41 of the housing cover 4 and allows the daughter substrates 2 to be arranged in the space. Since the daughter substrates 2 are not arranged on the main substrate 1 directly, this mounting configuration increases a degree of freedom of a pattern design in the main substrate 1, which reduces a designer's burden dramatically.

Further, in the mounting configuration of the substrates according to the present embodiment, the storage case 3 and the top board (the upper surface 41 of the housing cover 4) are made from conductive material (sheet metal member) and the storage case 3 is formed in an shape of a concave portion to have an open portion on the upper surface thereof. The storage case 3 is mounted to the housing cover 4 such that the open portion of the storage case 3 is opposed to the top board, which electromagnetically-shields the inside of the concave portion R.

This mounting configuration can effectively shield the daughter substrates 2 when the storage case 3 accommodates the daughter substrates 2 with high frequency circuit susceptible to electromagnetic wave.

Furthermore, in the mounting configuration of the substrates according to the present embodiment, the upper surface 41 of the housing case 4 is employed as the top board for mounting (suspending) the storage case 3. This mounting configuration can mount the daughter substrates 2 to the main substrate 1 with extremely simple structure.

Although the present invention has been described based on the present embodiment in detail, the present invention is not limited to the present embodiment and various changes may be made without departing from the scope of the present invention.

For example, although the storage case 3 is screwed to the housing cover 4 in the present embodiment, the storage case 3 may be fixed to the housing cover 4 using a proper engagement means (e.g., rail).

Further, for example, a top board independent of the housing cover 4 may be fixed to the housing cover 4 and the storage case 3 may be mounted to the top board. In this case, since the number of parts increases and the mounting configuration becomes complex, it is desirable that a top board is a part of the housing cover 4 as the present embodiment.

Although the storage case 3 and the housing cover 4 are made from sheet metal members in the present embodiment, the storage case 3 and the housing cover 4 may be made from conductive material. For example, the storage case 3 and the housing cover 4 may be made from plastic members subject to metallic plating or metallic mesh.

In a case where the daughter substrates 2 to be received in the storage case 3 are not susceptible to electromagnetic wave, the storage case 3 may be made from non-conductive material.

The present invention is not limited to an in-vehicle electronic device as the present embodiment and may be applied to various electronic devices. Since it is essential for the mounting configuration of substrates in the present invention to arrange the daughter substrates in the space between the main substrate and the housing cover, the mounting configuration may be turned upside down.

It should be understood that everything in the present embodiment is exemplary in the present invention. The scope of the present invention is determined by not the present embodiment but instead the scope of claims, and includes all modifications within the scope of claims.

What is claimed is:

1. An electronic device comprising:
a main substrate provided with an electronic part;
a top board arranged above the main substrate;
a daughter substrate electronically connected to the main substrate; and
a storage case accommodating the daughter substrate and mounted to the top board at an inner surface side of the top board.

2. The electronic device according to claim 1, wherein the top board is a part of a housing cover covering the main substrate.

3. The electronic device according to claim 1, wherein the storage case is formed in a shape of a concave portion to have an open portion on an upper surface thereof and mounted to the top board such that the open portion is opposed to the top board.

4. The electronic device according to claim 3, wherein the storage case and the top board are made from conductive material and the inside of the concave portion is electromagnetically-shield.
